(19) United States
(12) Patent Application Publication
(10) Pub. No.: US 2015/0168773 A1
(43) Pub. Date: Jun. 18, 2015

(54) THIN FILM TRANSISTOR ARRAY SUBSTRATE, MANUFACTURING METHOD THEREOF, AND LIQUID CRYSTAL DISPLAY DEVICE

(71) Applicant: Caiqin Chen, Shenzhen (CN)

(72) Inventor: Caiqin Chen, Shenzhen (CN)

(73) Assignee: SHENZHEN CHINA STAR OPTOELECTRONICS TECHNOLOGY CO., LTD., Shenzhen (CN)

(21) Appl. No.: 14/234,429

(22) PCT Filed: Dec. 19, 2013
(86) PCT No.: PCT/CN2013/089917

§ 371 Date: Jan. 23, 2014

(30) Foreign Application Priority Data
Dec. 13, 2013 (CN) 201310686690.6

(51) Int. Cl. G02F 1/1335; H01L 27/12

(52) U.S. Cl. CPC G02F 1/133514; H01L 27/124; H01L 27/1259; G02F 1/133512

(57) ABSTRACT

The present invention provides a thin film transistor array substrate. The thin film transistor array substrate includes a substrate, a black matrix layer, a gate layer, an insulation layer, a semiconductor layer, an ohmic contact layer, a second conductive layer, a passivation layer, and a transparent conductive layer. The second conductive layer includes a source layer and a drain layer. A gap exists between a projection area of the gate layer on the substrate and a projection area of the drain layer on the substrate. The present invention further provides a manufacturing method of the thin film transistor array substrate and a liquid crystal display device. The present invention improves the display effect of the liquid crystal display device.

### BACKGROUND OF THE INVENTION

1. Field of the Invention

The present invention generally relates to a liquid crystal display field, and more particularly to a thin film transistor array substrate, a manufacturing method thereof, and a liquid crystal display device.

2. Description of Prior Art

A liquid crystal display device has become a flat panel display device which is widely used by people. The liquid crystal display device generally comprises a thin film transistor (TFT) array substrate and a color filter (CF) substrate. Please refer to FIGS. 1A and 1B. FIG. 1A illustrates a top view of a conventional thin film transistor array substrate. FIG. 1B illustrates a sectional view along the section line A-A′ in FIG. 1A. The thin film transistor array substrate 10 comprises a source layer 11, a drain layer 12, a gate layer 13, an insulation layer 14, a semiconductor layer 15, an ohmic contact layer 16, a passivation layer 17, and a pixel electrode layer 18. The pixel electrode layer 18 may be connected to the drain layer 12 through a via hole 19.

The gate layer 13 is disposed at the bottom of the thin film transistor array substrate 10. The gate layer 13 needs not only to function as a gate, but also needs to avoid that light from the bottom and the sides of the thin film transistor array substrate 10 emits into the semiconductor 15 and to avoid that a photocurrent is generated. Accordingly, the area of the gate layer 13 should be larger. However, when the area of the gate layer 13 is larger, a parasitic capacitance between the gate layer 13 and the source layer 11 or between the gate layer 13 and the drain layer 12 is generated, and a feed-through voltage is generated in the meantime. As a result, the display effect of the liquid crystal display device is affected.

### SUMMARY OF THE INVENTION

An objective of the present invention is to provide a thin film transistor array substrate, a manufacturing method thereof, and a liquid crystal display device capable of solving the problems that the parasitic capacitance is larger and the photocurrent is larger in the conventional thin film transistor array substrate, the conventional manufacturing method, and the conventional liquid crystal display device.

To solve the above-mentioned problems, the technical scheme provided by the present invention is as follows.

A thin film transistor array substrate comprises:

a substrate;

a black matrix layer, a gate layer, an insulation layer, and a semiconductor layer which are sequentially formed on the substrate from bottom to top;

an ohmic contact layer positioned on a first area and a second area in the semiconductor layer which are separate from each other;

a second conductive layer comprising a source layer and a drain layer, the source layer connected to the ohmic contact layer on the first area, and the drain layer connected to the ohmic contact layer on the second area;

a passivation layer positioned on the source layer and the drain layer; and

a transparent conductive layer positioned on the passivation layer and electrically connected to the drain layer through a via hole,

Pixel electrodes are formed by patterning the transparent conductive layer, and a gap exists between a projection area of the gate layer on the substrate and a projection area of the drain layer on the substrate.

In the thin film transistor array substrate of the present invention, a gap exists between the projection area of the gate layer on the substrate and a projection area of the source layer on the substrate.

In the thin film transistor array substrate of the present invention, the black matrix layer is disposed between the substrate and the semiconductor layer for avoiding that light emits into the semiconductor layer from one side of the substrate.

In the thin film transistor array substrate of the present invention, the black matrix layer is manufactured of a chromium base material or a resin base material.

In the thin film transistor array substrate of the present invention, the gate layer, the source layer, and the drain layer are metal layers. The insulation layer and the passivation layer are nitride silicon layers. The semiconductor layer is an amorphous silicon layer. The ohmic contact layer is an amorphous silicon layer doped with phosphorus ions.

In the thin film transistor array substrate of the present invention, the transparent conductive layer is formed of indium tin oxide.

The present invention further provides a manufacturing method of a thin film transistor array substrate, which comprises:

forming a layered structure on a substrate, wherein the layered structure is a black matrix layer;

patterning the black matrix layer;

forming a first metal layer on the layered structure;

forming a gate layer by patterning the first metal layer;

sequentially forming an insulation layer, a semiconductor layer, an ohmic contact layer, and a second metal layer on the layered structure, the ohmic contact layer positioned on a first area and a second area in the semiconductor layer which are separate from each other;

forming a second conductive layer by patterning the second metal layer, the second metal layer comprising a source layer and a drain layer, the source layer connected to the ohmic metal layer on the first area, and the drain layer connected to the ohmic metal layer on the second area;

forming a passivation layer on the layered structure, and forming a via hole of the passivation layer by patterning the passivation layer; and

forming a transparent conductive layer on the layered structure, the transparent conductive layer electrically coupled to the drain layer through the via hole, and forming pixel electrodes by patterning the transparent conductive layer.

A gap exists between a projection area of the gate layer on the substrate and a projection area of the drain layer on the substrate.

In the manufacturing method of the thin film transistor array substrate of the present invention, a gap exists between the projection area of the gate layer on the substrate and a projection area of the source layer on the substrate,

In the manufacturing method of the thin film transistor array substrate of the present invention, the black matrix layer is disposed between the substrate and the semiconductor layer for avoiding that light emits into the semiconductor layer from one side of the substrate.

In the manufacturing method of the thin film transistor array substrate of the present invention, the black matrix layer is manufactured of a chromium base material or a resin base material.

In the manufacturing method of the thin film transistor array substrate of the present invention, the gate layer, the source layer, and the drain layer are metal layers. The insulation layer and the passivation layer are nitride silicon layers. The semiconductor layer is an amorphous silicon layer. The ohmic contact layer is an amorphous silicon layer doped with phosphorus ions.

In the manufacturing method of the thin film transistor array substrate of the present invention, the transparent conductive layer is formed of indium tin oxide.

The present invention further provides a liquid crystal display device, which comprises:

a color filter substrate, a thin film transistor array substrate, and a liquid crystal layer disposed between the color filter substrate and the thin film transistor array substrate,

the thin film transistor array substrate comprising:

a substrate;

a black matrix layer, a gate layer, an insulation layer, and a semiconductor layer which are sequentially formed on the substrate from bottom to top;

an ohmic contact layer positioned on a first area and a second area in the semiconductor layer which are separate from each other;

a second conductive layer comprising a source layer and a drain layer, the source layer connected to the ohmic contact layer on the first area, and the drain layer connected to the ohmic contact layer on the second area;

a passivation layer positioned on the source layer and the drain layer; and

a transparent conductive layer positioned on the passivation layer and electrically connected to the drain layer through a via hole.

Pixel electrodes are formed by patterning the transparent conductive layer, and a gap exists between a projection area of the gate layer on the substrate and a projection area of the drain layer on the substrate.

In the liquid crystal display device of the present invention, a gap exists between the projection area of the gate layer on the substrate and a projection area of the source layer on the substrate.

In the liquid crystal display device of the present invention, the black matrix layer is disposed between the substrate and the semiconductor layer for avoiding that light emits into the semiconductor layer from one side of the substrate.

In the liquid crystal display device of the present invention, the color filter substrate does not comprise another black matrix layer disposed thereon.

In the liquid crystal display device of the present invention, the black matrix layer is manufactured of a chromium base material or a resin base material.

In the liquid crystal display device of the present invention, the gate layer, the source layer, and the drain layer are metal layers. The insulation layer and the passivation layer are nitride silicon layers. The semiconductor layer is an amorphous silicon layer. The ohmic contact layer is an amorphous silicon layer doped with phosphorus ions.

In the liquid crystal display device of the present invention, the transparent conductive layer is formed of indium tin oxide.

Compared with the conventional thin film transistor array substrate, the conventional manufacturing method, and the conventional liquid crystal display device, the thin film transistor array substrate, the manufacturing method thereof, and the liquid crystal display device of the present invention are capable of decreasing the generation of the photocurrent by disposing the black matrix layer on the substrate and reducing the parasitic capacitance between the gate layer and the source layer and the parasitic capacitance between the gate layer and the drain layer by decreasing the area of the gate layer. As a result, the problems that the parasitic capacitance is larger and the photocurrent is larger in the conventional thin film transistor array substrate, the conventional manufacturing method, and the conventional liquid crystal display device can be solved.

For a better understanding of the aforementioned content of the present invention, preferable embodiments are illustrated in accordance with the attached figures for further explanation:

### BRIEF DESCRIPTION OF THE DRAWINGS

FIG. 1A illustrates a top view of a conventional thin film transistor array substrate;

FIG. 1B illustrates a sectional view along the section line A-A′ in FIG. 1A;

FIG. 2 illustrates a structural diagram of a thin film transistor array substrate in accordance with a preferred embodiment of the present invention;

FIG. 3 illustrates a flow chart of a manufacturing method of a thin film transistor array substrate in accordance with a preferred embodiment of the present invention;

FIG. 4A illustrates a top view when step S101 is performed in the manufacturing method of the thin film transistor array substrate in accordance with the preferred embodiment;

FIG. 4B illustrates a sectional view along the section line B-B′ in FIG. 4A;

FIG. 5A illustrates a top view when step S102 is performed in the manufacturing method of the thin film transistor array substrate in accordance with the preferred embodiment;

FIG. 5B illustrates a sectional view along the section line C-C′ in FIG. 5A;

FIG. 6A illustrates a top view when step S104 is performed in the manufacturing method of the thin film transistor array substrate in accordance with the preferred embodiment;

FIG. 6B illustrates a sectional view along the section line D-D′ in FIG. 6A;

FIG. 7A illustrates a top view when step S105 is performed in the manufacturing method of the thin film transistor array substrate in accordance with the preferred embodiment;

FIG. 7B illustrates a sectional view along the section line E-E′ in FIG. 7A; and

FIG. 8 illustrates a top view when step S106 is performed in the manufacturing method of the thin film transistor array substrate in accordance with the preferred embodiment.

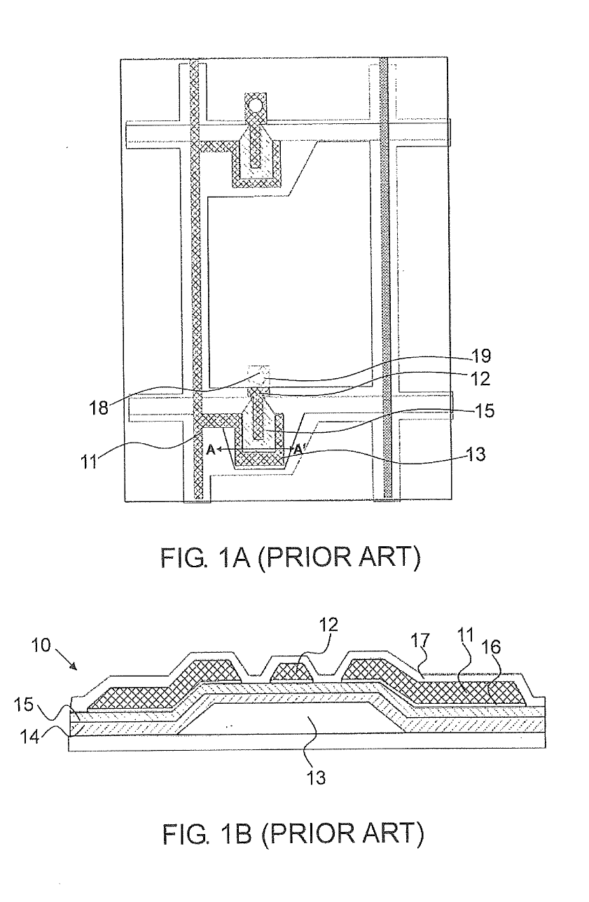

### DETAILED DESCRIPTION OF THE INVENTION

The following descriptions for the respective embodiments are specific embodiments capable of being implemented for illustrations of the present invention with referring to appended figures. For example, the terms of up, down, front, rear, left, right, interior, exterior, side, etcetera are merely directions of referring to appended figures. Therefore, the wordings of directions are employed for explaining and understanding the present invention but not limitations thereto.

In the appended figures, elements having similar structures are represented as the same numeral.

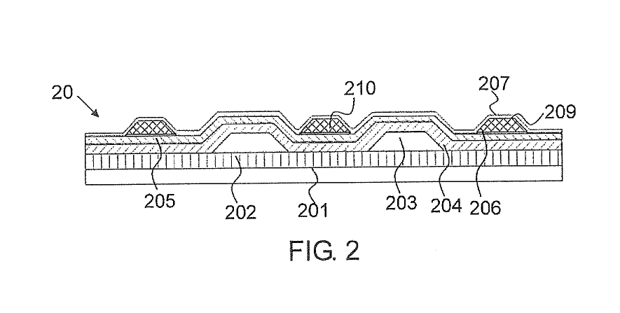

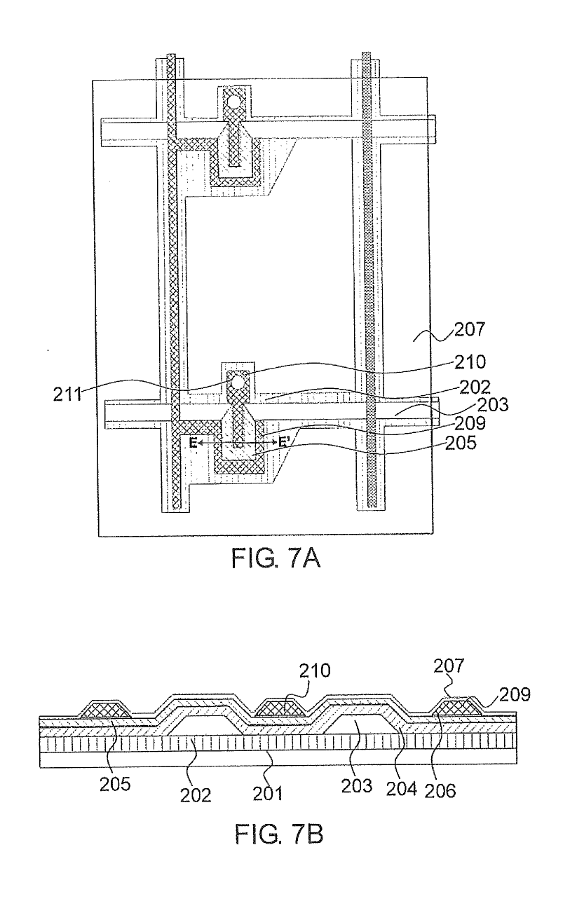

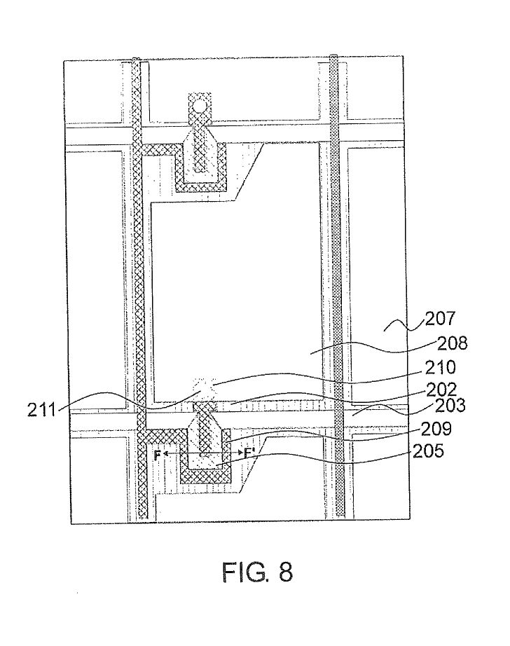

Please refer to FIG. 2. FIG. 2 illustrates a structural diagram of a thin film transistor array substrate 20 in accordance with a preferred embodiment of the present invention. The thin film transistor array substrate 20 in accordance with the preferred embodiment comprises a substrate 201, a black matrix layer 202, a gate layer 203, an insulation layer 204, a semiconductor layer 205, an ohmic contact layer 206, a second conductive layer, a passivation layer 207, and a transparent conductive layer 208 which are sequentially formed on the substrate 201 from the bottom to the top. The ohmic contact layer 206 is positioned on a first area and a second area in the semiconductor layer 205 which are separate from each other. The second conductive layer comprises a source layer 209 and a drain layer 210. The source layer 209 is connected to the ohmic contact layer 206 on the first area, and the drain layer 210 is connected to the ohmic contact layer 206 on the second area. The passivation layer 207 is positioned on the source layer 209 and the drain layer 210. The transparent conductive layer 208 (as shown in FIG. 7 and FIG. 8) is positioned on the passivation layer 207 and electrically connected to the drain layer 210 through a via hole 211 (as shown in FIG. 7 and FIG. 8).

In the preferred embodiment, the black matrix layer 202 is utilized for blocking light leakage of a backlight source from areas excluding pixel areas. In the meantime, the black matrix layer 202 prevents the color mixture between adjacent two of RGB subpixels on a color filter substrate (the part of the black matrix layer 202 for preventing the color mixture is not shown in FIG. 2) and prevents the entrance of ambient light. The black matrix layer 202 may be manufactured of a chromium base material or a resin base material, and it is formed on the substrate 201 by a patterning process. The gate layer 203 is a metal layer, for instance, nobelium, molybdenum, aluminum, copper, titanium, tantalum, or tungsten. The insulation layer 204 may be a nitride silicon layer. The semiconductor layer 205 may be an amorphous silicon layer. The ohmic contact layer 206 may be an amorphous silicon layer doped with phosphorus ions. The source layer 209 and the drain layer 210 are metal layers. The passivation layer 207 may be a nitride silicon layer. The transparent conductive layer 208 may be formed of indium tin oxide, and pixel electrodes may be formed by patterning the transparent conductive layer 208. A gap exists between a projection area of the gate layer 203 on the substrate 201 and a projection area of the drain layer 210 on the substrate 201, and a gap also exists between the projection area of the gate layer 203 on the substrate 201 and a projection area of the source layer 209 on the substrate 201. That is, the projection area of the gate layer 203 on the substrate 201 and the projection area of the drain layer 210 on the substrate 201 do not overlap, and the projection area of the gate layer 203 on the substrate 201 and the projection area of the source layer 209 on the substrate 201 do not overlap, either.

When the thin film transistor array substrate 20 in accordance with the preferred embodiment is used, the black matrix layer 202 can effectively avoid that the light emits into the semiconductor layer 205 from one side of the substrate 201 because the black matrix layer 202 is disposed between the substrate 201 and the semiconductor layer 205. As a result, a photocurrent in the semiconductor layer 205 is not generated. Furthermore, the area of the gate layer 203 is decreased, so that the projection area of the gate layer 203 on the substrate 201 and the projection area of the drain layer 210 on the substrate 201 do not overlap, and the projection area of the gate layer 203 on the substrate 201 and the projection area of the source layer 209 on the substrate 201 do not overlap. The parasitic capacitance between the gate layer 203 and the source layer 209 and the parasitic capacitance between the gate layer 203 and the drain layer 210 can be reduced significantly, thereby improving the display effect of a corresponding liquid crystal display device.

In summary, the thin film transistor array substrate of the present invention prevents the generation of the photocurrent by disposing the black matrix layer on the thin film transistor array substrate and reduces the parasitic capacitance between the gate layer and the source layer and the parasitic capacitance between the gate layer and the drain layer by decreasing the area of the gate layer.

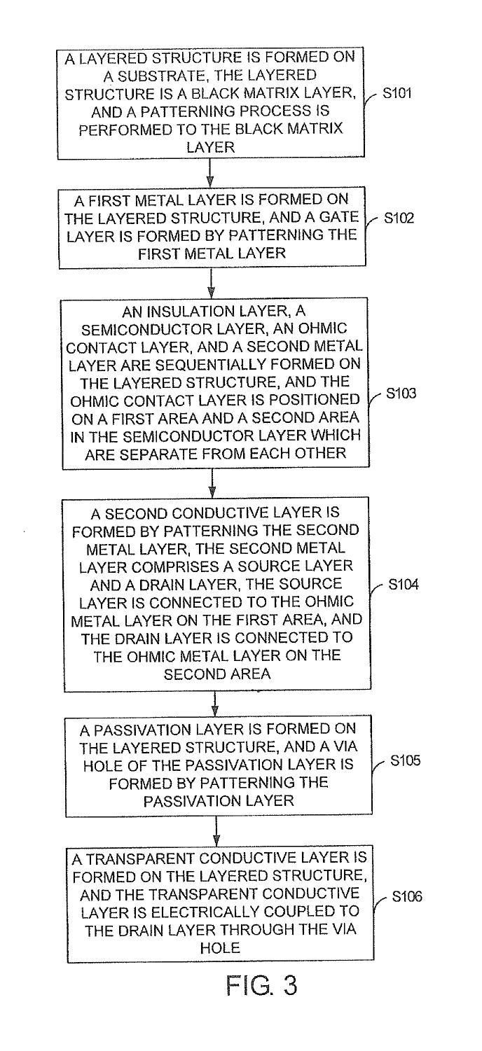

Please refer to FIG. 3. FIG. 3 illustrates a flow chart of a manufacturing method of a thin film transistor array substrate in accordance with a preferred embodiment of the present invention. The manufacturing method of the thin film transistor array substrate in accordance with the preferred embodiment comprises the following steps.

In step S101, a layered structure is formed on a substrate. The layered structure is a black matrix layer, and a patterning process is performed to the black matrix layer.

In step S102, a first metal layer is formed on the layered structure, and a gate layer is formed by patterning the first metal layer.

In step S103, an insulation layer, a semiconductor layer, an ohmic contact layer, and a second metal layer are sequentially formed on the layered structure. The ohmic contact layer is positioned on a first area and a second area in the semiconductor layer which are separate from each other.

In step S104, a second conductive layer is formed by patterning the second metal layer. The second metal layer comprises a source layer and a drain layer. The source layer is connected to the ohmic metal layer on the first area, and the drain layer is connected to the ohmic metal layer on the second area.

In step S105, a passivation layer is formed on the layered structure, and a via hole of the passivation layer is formed by patterning the passivation layer.

In step S106, a transparent conductive layer is formed on the layered structure, and the transparent conductive layer is electrically coupled to the drain layer through the via hole.

The manufacturing method of the thin film transistor array substrate in accordance with the preferred embodiment ends in step S106.

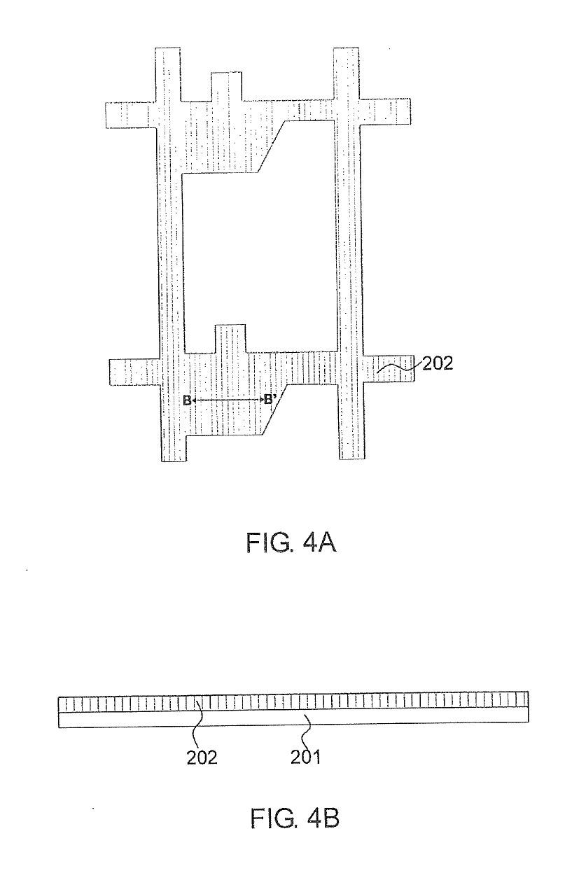

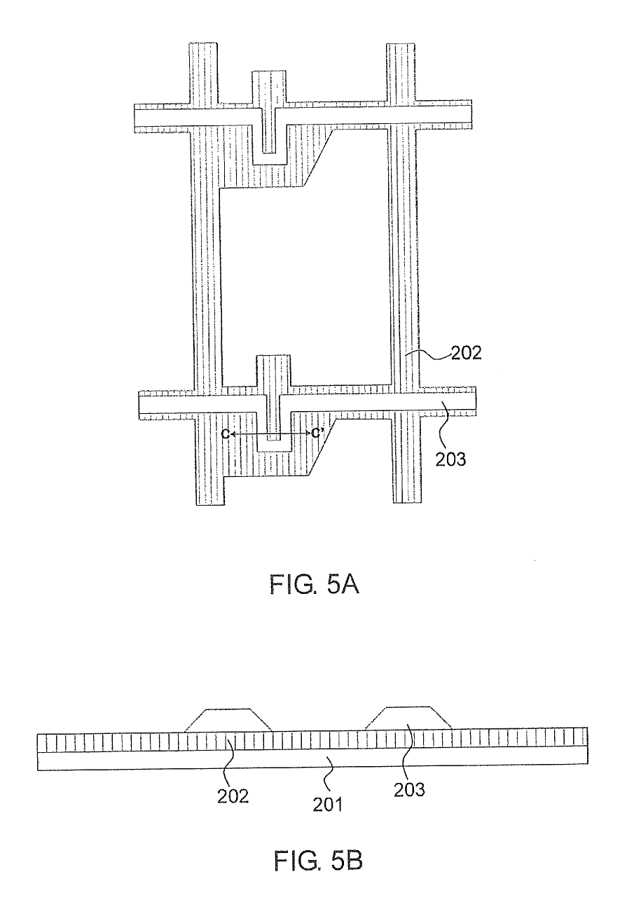

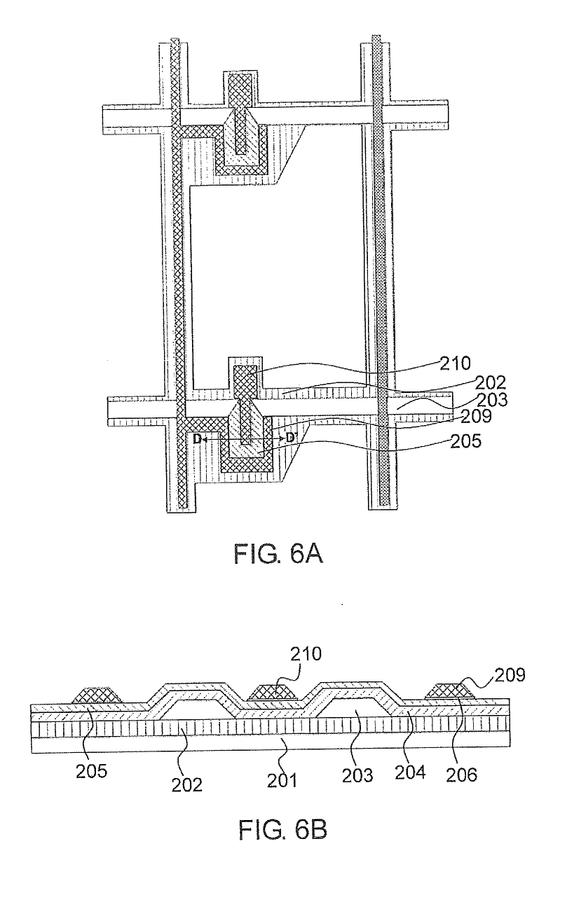

The specific steps in the manufacturing method of the thin film transistor array substrate in accordance with the preferred embodiment will be described in FIG. 4A to FIG. BB. FIG. 4A illustrates a top view when step S101 is performed in the manufacturing method of the thin film transistor array substrate in accordance with the preferred embodiment. FIG. 4B illustrates a sectional view along the section line B-B′ in FIG. 4A. FIG. 5A illustrates a top view when step S102 is performed in the manufacturing method of the thin film transistor array substrate in accordance with the preferred embodiment. FIG. 5B illustrates a sectional view along the section line CC′ in FIG. 5A. FIG. 6A illustrates a top view when step S104 is performed in the manufacturing method of the thin film transistor array substrate in accordance with the preferred embodiment. FIG. 6B illustrates a sectional view along the section line D-D′ in FIG. 6A. FIG. 7A illustrates a top view when step S105 is performed in the manufacturing method of the thin film transistor array substrate in accordance with the preferred embodiment. FIG. 7B illustrates a sectional view along the section line E-E′ in FIG. 7A. FIG. 8 illustrates a top view when step S106 is performed in the manufacturing method of the thin film transistor array substrate in accordance with the preferred embodiment.

In step S101, the layered structure is formed on the substrate 201. The layered structure is the black matrix layer 202. The black matrix layer 202 is utilized for blocking the light of the backlight source from the areas excluding the pixel areas, preventing the color mixture between adjacent two of RGB subpixels on a color filter substrate (the part of the black matrix layer 202 for preventing the color mixture is not shown in FIG. 4A), and preventing the entrance of ambient light. The black matrix layer 202 may be manufactured of a chromium base material or a resin base material. The black matrix layer 202 may be formed on the substrate 201 by a patterning process with a corresponding photomask. The structure of the thin film transistor array substrate after the patterning process is shown in FIG. 4B. Then, step S102 is performed.

In step S102, the first metal layer is formed on the layered structure. The first metal layer may be nobelium, molybdenum, aluminum, copper, titanium, tantalum, or tungsten. Then, the gate layer 203 is formed by patterning the first metal layer with a corresponding photomask. The structure of the thin film transistor array substrate after the patterning process is shown in FIG. 5B. Then, step S103 is performed.

In step S103, the insulation layer 204, the semiconductor layer 205, the ohmic contact layer 206, and the second metal layer are sequentially formed on the layered structure. The ohmic contact layer 206 is positioned on the first area and the second area in the semiconductor layer 205 which are separate from each other. The insulation layer 204 is a nitride silicon layer. The semiconductor layer 205 may be an amorphous silicon layer. The ohmic contact layer 206 may be an amorphous silicon layer doped with phosphorus ions. The material of the second metal layer may be nobelium, molybdenum, aluminum, copper, titanium, tantalum, or tungsten. Then, step S104 is performed.

In step S104, the second conductive layer is formed by patterning the second metal layer with a corresponding photomask. The second conductive layer comprises the source layer 209 and the drain layer 210. The source layer 209 is connected to the ohmic metal layer 206 on the first area, and the drain layer 210 is connected to the ohmic metal layer 206 on the second area. Herein, a gap exists between a projection area of the gate layer 203 on the substrate 201 and a projection area of the drain layer 210 on the substrate 201, and a gap also exists between the projection area of the gate layer 203 on the substrate 201 and a projection area of the source layer 209 on the substrate 201. That is, the projection area of the gate layer 203 on the substrate 201 and the projection area of the drain layer 210 on the substrate 201 do not overlap, and the projection area of the gate layer 203 on the substrate 201 and the projection area of the source layer 209 on the substrate 201 do not overlap, either. The structure of the thin film transistor array substrate after the patterning process is shown in FIG. 6B. Then, step S105 is performed.

In step S105, the passivation layer 207 is formed on the layered structure. The via hole 211 of the passivation layer 207 is formed by patterning the passivation layer 207 with a corresponding photomask. The passivation layer 207 may be a nitride silicon layer. The structure of the thin film transistor array substrate after the patterning process is shown in FIG. 7B. Then, step S106 is performed.

In step S106, the transparent conductive layer 208 is formed on the layered structure. The transparent conductive layer 208 is electrically coupled to the drain layer 210 through the via hole 211 of the passivation layer 207 by patterning the transparent conductive layer 208 with a corresponding photomask. The transparent conductive layer 208 may be formed of indium tin oxide, and the pixel electrodes may be formed by patterning the transparent conductive layer 208. The structure of the thin film transistor array substrate after the patterning process is shown in FIG. 8 and FIG. 7B (the sectional view along the section line F-F′ in FIG. 8 is the same as that in FIG. 7B).

After the above-mentioned steps, the manufacturing method of thin film transistor array substrate in accordance with the preferred embodiment ends.

In the thin film transistor array substrate manufactured by the manufacturing method of the thin film transistor array substrate in accordance with the preferred embodiment, the black matrix layer 202 can effectively avoid that the light emits into the semiconductor layer 205 from one side of the substrate 201 because the black matrix layer 202 is disposed between the substrate 201 and the semiconductor layer 205. As a result, the photocurrent in the semiconductor layer 205 is not generated. Furthermore, the area of the gate layer 203 is decreased, so that the projection area of the gate layer 203 on the substrate 201 and the projection area of the drain layer 210 on the substrate 201 do not overlap, and the projection area of the gate layer 203 on the substrate 201 and the projection area of the source layer 209 on the substrate 201 do not overlap. The parasitic capacitance between the gate layer 203 and the source layer 209 and the parasitic capacitance between the gate layer 203 and the drain layer 210 can be reduced significantly, thereby improving the display effect of the corresponding liquid crystal display device.

In summary, the manufacturing method of the thin film transistor array substrate of the present invention prevents the generation of the photocurrent by disposing the black matrix layer on the substrate and reduces the parasitic capacitance between the gate layer and the source layer and the parasitic capacitance between the gate layer and the drain layer by decreasing the area of the gate layer.

The present invention further provides a liquid crystal display device. The liquid crystal display device comprises a color filter substrate, a thin film transistor array substrate, and a liquid crystal layer disposed between the color filter substrate and the thin film transistor array substrate.

The thin film transistor array substrate comprises a substrate, a black matrix layer, a gate layer, an insulation layer, a semiconductor layer, an ohmic contact layer, a second conductive layer, a passivation layer, and a transparent conductive layer which are sequentially formed on the substrate from the bottom to the top. The ohmic contact layer is positioned on a first area and a second area in the semiconductor layer which are separate from each other. The second conductive layer comprises a source layer and a drain layer. The source layer is connected to the ohmic contact layer on the first area, and the drain layer is connected to the ohmic contact layer on the second area. The passivation layer is positioned on the source layer and the drain layer. The transparent conductive layer is positioned on the passivation layer and electrically connected to the drain layer through a via hole. Pixel electrodes are formed by patterning the transparent conductive layer.

A gap exists between a projection area of the gate layer on the substrate and a projection area of the drain layer on the substrate, and a gap also exists between the projection area of the gate layer on the substrate and a projection area of the source layer on the substrate. The black matrix layer is disposed between the substrate and the semiconductor layer for avoiding that the light emits into the semiconductor layer from one side of the substrate. Since the thin film transistor array substrate comprises the black matrix layer disposed thereon, the color filter substrate does not require a black matrix layer for reducing the cost of the liquid crystal display device.

The particular operational principle of the liquid crystal display device of the present invention is the same as that of the above-mentioned thin film transistor array substrate in accordance with the preferred embodiment. The particular operational principle can be referred to the related descriptions in the above-mentioned thin film transistor array substrate in accordance with the preferred embodiment.

The thin film transistor array substrate, the manufacturing method thereof, and the liquid crystal display device of the present invention are capable of decreasing the generation of the photocurrent by disposing the black matrix layer on the substrate and reducing the parasitic capacitance between the gate layer and the source layer and the parasitic capacitance between the gate layer and the drain layer by decreasing the area of the gate layer, so that the problems that the parasitic capacitance is larger and the photocurrent is larger in the conventional thin film transistor array substrate, the conventional manufacturing method, and the conventional liquid crystal display device can be solved.

As is understood by a person skilled in the art, the foregoing preferred embodiments of the present invention are illustrative rather than limiting of the present invention. It is intended that they cover various modifications and similar arrangements be included within the spirit and scope of the appended claims, the scope of which should be accorded the broadest interpretation so as to encompass all such modifications and similar structure.

What is claimed is:

1. A thin film transistor array substrate, comprising:
a substrate;
a black matrix layer, a gate layer, an insulation layer, and a semiconductor layer which are sequentially formed on the substrate from bottom to top;
an ohmic contact layer positioned on a first area and a second area in the semiconductor layer which are separate from each other;
a second conductive layer comprising a source layer and a drain layer, the source layer connected to the ohmic contact layer on the first area, and the drain layer connected to the ohmic contact layer on the second area;
a passivation layer positioned on the source layer and the drain layer; and
a transparent conductive layer positioned on the passivation layer and electrically connected to the drain layer through a via hole,
wherein pixel electrodes are formed by patterning the transparent conductive layer, and a gap exists between a projection area of the gate layer on the substrate and a projection area of the drain layer on the substrate.

2. The thin film transistor array substrate of claim 1, wherein a gap exists between the projection area of the gate layer on the substrate and a projection area of the source layer on the substrate.

3. The thin film transistor array substrate of claim 1, wherein the black matrix layer is disposed between the substrate and the semiconductor layer for avoiding that light emits into the semiconductor layer from one side of the substrate.

4. The thin film transistor array substrate of claim 1, wherein the black matrix layer is manufactured of a chromium base material or a resin base material.

5. The thin film transistor array substrate of claim 1, wherein the gate layer, the source layer, and the drain layer are metal layers, the insulation layer and the passivation layer are nitride silicon layers, the semiconductor layer is an amorphous silicon layer, and the ohmic contact layer is an amorphous silicon layer doped with phosphorus ions.

6. The thin film transistor array substrate of claim 1, wherein the transparent conductive layer is formed of indium tin oxide.

7. A manufacturing method of a thin film transistor array substrate, comprising:
forming a layered structure on a substrate, wherein the layered structure is a black matrix layer;
patterning the black matrix layer;
forming a first metal layer on the layered structure;
forming a gate layer by patterning the first metal layer;
sequentially forming an insulation layer, a semiconductor layer, an ohmic contact layer, and a second metal layer on the layered structure, the ohmic contact layer positioned on a first area and a second area in the semiconductor layer which are separate from each other;
forming a second conductive layer by patterning the second metal layer, the second metal layer comprising a source layer and a drain layer, the source layer connected to the ohmic metal layer on the first area, and the drain layer connected to the ohmic metal layer on the second area;
forming a passivation layer on the layered structure, and forming a via hole of the passivation layer by patterning the passivation layer; and
forming a transparent conductive layer on the layered structure, the transparent conductive layer electrically coupled to the drain layer through the via hole, and forming pixel electrodes by patterning the transparent conductive layer,
wherein a gap exists between a projection area of the gate layer on the substrate and a projection area of the drain layer on the substrate.

8. The manufacturing method of the thin film transistor array substrate of claim 7, wherein a gap exists between the projection area of the gate layer on the substrate and a projection area of the source layer on the substrate.

9. The manufacturing method of the thin film transistor array substrate of claim 7, wherein the black matrix layer is disposed between the substrate and the semiconductor layer for avoiding that light emits into the semiconductor layer from one side of the substrate.

10. The manufacturing method of the thin film transistor array substrate of claim 7, wherein the black matrix layer is manufactured of a chromium base material or a resin base material.

11. The manufacturing method of the thin film transistor array substrate of claim 7, wherein the gate layer, the source layer, and the drain layer are metal layers, the insulation layer and the passivation layer are nitride silicon layers, the semiconductor layer is an amorphous silicon layer, and the ohmic contact layer is an amorphous silicon layer doped with phosphorus ions.

12. The manufacturing method of the thin film transistor array substrate of claim 7, wherein the transparent conductive layer is formed of indium tin oxide.

13. A liquid crystal display device, comprising:
a color filter substrate, a thin film transistor array substrate, and a liquid crystal layer disposed between the color filter substrate and the thin film transistor array substrate,
the thin film transistor array substrate comprising:
a substrate;
a black matrix layer, a gate layer, an insulation layer, and a semiconductor layer which are sequentially formed on the substrate from bottom to top;
an ohmic contact layer positioned on a first area and a second area in the semiconductor layer which are separate from each other;
a second conductive layer comprising a source layer and a drain layer, the source layer connected to the ohmic contact layer on the first area, and the drain layer connected to the ohmic contact layer on the second area;
a passivation layer positioned on the source layer and the drain layer; and
a transparent conductive layer positioned on the passivation layer and electrically connected to the drain layer through a via hole,
wherein pixel electrodes are formed by patterning the transparent conductive layer, and a gap exists between a projection area of the gate layer on the substrate and a projection area of the drain layer on the substrate.

14. The liquid crystal display device of claim 13, wherein a gap exists between the projection area of the gate layer on the substrate and a projection area of the source layer on the substrate.

15. The liquid crystal display device of claim 13, wherein the black matrix layer is disposed between the substrate and the semiconductor layer for avoiding that light emits into the semiconductor layer from one side of the substrate.

16. The liquid crystal display device of claim 13, wherein the color filter substrate does not comprise another black matrix layer disposed thereon.

17. The liquid crystal display device of claim 13, wherein the black matrix layer is manufactured of a chromium base material or a resin base material.

18. The liquid crystal display device of claim 13, wherein the gate layer, the source layer, and the drain layer are metal layers, the insulation layer and the passivation layer are nitride silicon layers, the semiconductor layer is an amorphous silicon layer, and the ohmic contact layer is an amorphous silicon layer doped with phosphorus ions.

19. The liquid crystal display device of claim 13, wherein the transparent conductive layer is formed of indium tin oxide.
